(19) United States
(12) Patent Application Publication
(10) Pub. No.: US 2026/0006814 A1
(43) Pub. Date: Jan. 1, 2026

(54) SINGLE-CRYSTALLINE AL2O3 DIELECTRIC COMPATIBLE WITH TWO-DIMENSIONAL MATERIALS AND INTEGRATED DEVICE THEREOF

(71) Applicant: SHANGHAI INSTITUTE OF MICROSYSTEM AND INFORMATION TECHNOLOGY CHINESE ACADEMY OF SCIENCES, Shanghai (CN)

(72) Inventors: Zeng Feng Di, Shanghai (CN); Zi Ao Tian, Shanghai (CN); Dao Bing Zeng, Shanghai (CN); Miao Zhang, Shanghai (CN); Jie Jun Zhang, Shanghai (CN)

(73) Assignee: SHANGHAI INSTITUTE OF MICROSYSTEM AND INFORMATION TECHNOLOGY CHINESE ACADEMY OF SCIENCES, Shanghai (CN)

(21) Appl. No.: 19/026,541

(22) Filed: Jan. 17, 2025

(30) Foreign Application Priority Data
Jun. 28, 2024 (CN) 202410851399.8

(51) Int. Cl. H10D 30/01; C30B 1/10; C30B 29/20

(52) U.S. Cl. CPC H10D 30/017; C30B 1/10; C30B 29/20

(57) ABSTRACT

The present invention relates to a single-crystalline Al₂O₃ dielectric compatible with two-dimensional materials and an integrated device thereof. A single-crystalline Al thin film is produced on a single-crystalline graphene/germanium (110) substrate via the van der Waals (vdW) epitaxy approach, the single-crystalline Al thin film is peeled off from the graphene/germanium substrate, and intercalative oxidation is performed to produce the single-crystalline Al₂O₃ dielectric compatible with two-dimensional materials on the lower surface of the single-crystalline Al thin film. The gate leakage current (J<1×10⁻⁵ A cm⁻²), interface state density (Dᵢₜ=8.4×10⁹ cm⁻² eV⁻¹), and dielectric strength (E_{bd}=17.4 MV/cm) of the single-crystalline Al₂O₃ dielectric obtained in the present invention can meet the requirements of the international roadmap for devices and systems (IRDS) for low power consumption devices.

### CROSS-REFERENCE TO RELATED APPLICATION

This application claims the priority benefit of China application serial no. 202410851399.8, filed on Jun. 28, 2024. The entirety of the above-mentioned patent application is hereby incorporated by reference herein and made a part of this specification.

### BACKGROUND

### Technical Field

The present invention belongs to the field of semiconductor devices and particularly relates to a single-crystalline Al₂O₃ dielectric compatible with two-dimensional materials and an integrated device thereof.

### Description of Related Art

The feature size of silicon-based field effect transistors has been scaled to a physical limit, thus it is necessary to introduce a new generation of semiconductor channel materials at a node of 2 nm or below to overcome short channel effects and power consumption bottlenecks. Due to their atomically thin thickness and high carrier mobility, two-dimensional semiconductor materials such as MoS₂ are considered as candidate channel materials for future transistors. However, due to the lack of high-quality dielectrics, two-dimensional transistors cannot exhibit their excellent physical and electrical performance theoretically beyond silicon. Amorphous oxide dielectrics such as SiO₂, Al₂O₃ and HfO₂, which are widely used in silicon-based transistors, cannot form uniform and well-defined interfaces with two-dimensional materials due to surface dangling bonds and long-range disorder. The amorphous nature and not well-defined interfaces will introduce charge scattering and interface traps, resulting in large gate leakage current (J>1.5×10⁻² A cm⁻²), high interface state density (Dᵢₜ>10¹⁰ cm⁻² eV⁻¹), and low breakdown field strength (E_{bd}<10 MV/cm), which make two-dimensional transistors unable to meet the requirements of the international roadmap for devices and systems (IRDS) for future low power consumption devices. In addition, the nondestructive preparation of atomically thin oxide dielectrics on the surface of two-dimensional materials by directly using an atomic layer deposition process also faces a great challenge due to the inert and dangling-bond-free surface of two-dimensional materials.

Compared with amorphous oxides, crystalline dielectric materials such as hexagonal boron nitride (h-BN), calcium fluoride (CaF₂), and strontium titanate (SrTiO₃) have atomically flat surfaces and can form atomically sharp dielectric-two-dimensional material interfaces with two-dimensional materials. In theory, the crystalline dielectric materials can solve the problems of interface quality and wide defect band of amorphous oxides. However, crystalline dielectrics for two-dimensional transistors also face some problems. For example, two-dimensional h-BN with an ultra-thin physical thickness exhibits extremely high gate leakage current (>103 A/cm) due to relatively narrow bandgap and low dielectric constant, making it impossible to scale the equivalent oxide thickness (EOT) to 1 nm or below. Although β-Bi₂SeO₅ can scale the EOT to 0.5 nm or below, it is a natural oxide formed on the surface of Bi₂O₂Se and may not be compatible with other two-dimensional semiconductors. CaF₂ and SrTiO₃ are not only difficult to prepare and require complicated growth processes such as molecular beam epitaxy and pulsed laser deposition, but also limited to back-gate two-dimensional field effect transistors. However, large-scale integrated circuits require top-gate transistors indeed. In addition, achieving the interface state density of lower than 10¹⁰ cm⁻² eV⁻¹ in crystalline dielectric two-dimensional transistor devices and wafer-level preparation of high-quality crystalline dielectrics remains a challenge. Since currently there is still no universal and reliable method to scale dielectric materials of two-dimensional transistors to atomically thin thicknesses (EOT<1 nm) as required by commercial transistors, the development of crystalline dielectric preparation and dielectric integration processes suitable for two-dimensional transistors is critical to achieve high-performance two-dimensional electronic devices.

### SUMMARY

The technical problem to be solved by the present invention is to provide a single-crystalline Al₂O₃ dielectric compatible with two-dimensional materials and an integrated device thereof. The gate leakage current (J<1×10⁻⁵ A cm⁻²), interface state density (Dᵢₜ=8.4×10⁹ cm⁻² eV⁻¹), and dielectric strength (E_{bd}=17.4 MV/cm) of the single-crystalline Al₂O₃ dielectric can meet the requirements of the international roadmap for devices and systems (IRDS) for low power consumption devices.

The present invention provides a single-crystalline Al₂O₃ dielectric compatible with two-dimensional materials. Van der Waals (vdW) epitaxy of a single-crystalline Al thin film is performed on a single-crystalline graphene/germanium (110) substrate, the single-crystalline Al thin film is peeled off from the graphene/germanium substrate, and intercalative oxidation is performed to produce the single-crystalline Al₂O₃ dielectric compatible with two-dimensional materials on the lower surface of the single-crystalline Al thin film.

The present invention also provides a preparation method for a single-crystalline Al₂O₃ dielectric compatible with two-dimensional materials, including the steps of:
(1) defining Al metal patterns on a single-crystalline graphene/germanium substrate by electron beam lithography/ultraviolet photolithography, and then allowing a single-crystalline Al thin film to epitaxially grow on the graphene/germanium substrate by electron beam evaporation; and after a lift-off process, allowing a patterned single-crystalline Al thin film to be left on the graphene/germanium substrate;
(2) physically laminating a PVA film on an elastic polydimethylsiloxane (PDMS) stamp onto the patterned single-crystalline Al thin film in the step (1) with a transfer platform in a glovebox, and performing heating, releasing a vitrified PVA film from PDMS onto the graphene/germanium substrate, then cooling the substrate to room temperature;
(3) peeling off the PVA film from the graphene/germanium substrate, and peeling off the patterned single-crystalline Al thin film in the step (1) from the graphene/germanium substrate onto the PVA film in an oxygen-deficient environment of a glovebox, and forming atomically thin single-crystalline c-Al₂O₃, i.e., the single-crystalline Al₂O₃ dielectric compatible with two-dimensional materials, on the lower surface of the patterned single-crystalline Al thin film.

Preferably, the heating in the step (2) is performed at a temperature of 80-100° C. for 1-5 min.

Preferably, the oxygen-deficient environment of the glovebox in the step (3) refers to an oxygen concentration of 0.2 ppm or less.

The present invention also provides use of the single-crystalline Al₂O₃ dielectric compatible with two-dimensional materials in the manufacture of an integrated device.

Preferably, the integrated device is a two-dimensional field effect transistor or a two-dimensional transistor array thereof.

Preferably, a method for manufacturing the two-dimensional field effect transistor includes the steps of:
(1) defining a gate electrode pattern by electron beam lithography/ultraviolet photolithography, allowing a single-crystalline Al metal gate electrode to epitaxially grow on a graphene/germanium substrate by electron beam evaporation, and allowing an upper surface and a side wall of the Al gate electrode to be naturally oxidized in air to form amorphous aluminum oxide;
(2) defining source-drain contact patterns on both sides of the Al gate electrode by electron beam lithography/ultraviolet photolithography, and allowing Au to deposit on both sides of the gate electrode by electron beam evaporation as source-drain contact electrodes;
(3) peeling off the Al gate electrode and the source-drain Au contact electrodes from the graphene/germanium substrate with a PVA film in an oxygen-deficient environment of a glovebox, and subjecting the lower surface of the Al gate electrode to an intercalative oxidation process to produce c-Al₂O₃ dielectric;
(4) attaching the PVA film, which carries the Au contact electrodes and Al/c-Al₂O₃ gate stacks, to PDMS, and then aligning and physically laminating a transistor structure attached to a PDMS/PVA stamp onto mechanically exfoliated or CVD-grown two-dimensional materials using a transfer platform;
(5) dissolving the PVA film with an organic solvent to obtain the two-dimensional field effect transistor.

Preferably, the two-dimensional transistor array is obtained by mass production of the manufactured two-dimensional field effect transistors.

### Beneficial Effects

(1) The present invention combines epitaxial lift off and intercalative oxidation techniques to prepare an atomically thin single-crystalline c-Al₂O₃ layer with a thickness thinner than that of traditional oxides used in advanced process silicon transistors. The gate leakage current (J<1×10⁻⁵ A cm⁻²), interface state density (Dᵢₜ=8.4×10⁹ cm⁻² eV⁻¹), and dielectric strength (E_{bd}=17.4 MV/cm) of the atomically thin single-crystalline c-Al₂O₃ can meet the requirements of the international roadmap for devices and systems (IRDS) for low power consumption devices due to the good crystalline structure and well-defined interfaces.
(2) Two-dimensional field effect transistors with high quality contacts and dielectric interfaces can be manufactured by one-step van der Waals transfer of the entire field effect transistor functional stack (including sources, drains, dielectric and gates) onto the MoS₂ channel in the present invention. The two-dimensional field effect transistor of the present invention has a steep subthreshold swing (SS) of 61 mV/dec, an ultra-high current on/off ratio (Iₒₙ/I_{off}) of 10⁸, and a negligible hysteresis of 10 mV. The repeatability and uniformity of the process are demonstrated by batch manufacture of MoS₂ field effect transistors.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of the preparation of atomically thin single-crystalline c-Al₂O₃ according to the present invention.

FIG. 2 is a schematic diagram and optical image of a graphene-assisted water-free transfer process of Al/c-Al₂O₃ patterns, wherein: (a) a schematic diagram of the water-free transfer process of the Al/c-Al₂O₃ pattern under an oxygen-deficient environment (0.2 ppm O₂) in a glovebox; (b) a photograph of the Al/c-Al₂O₃ pattern transferred onto a four-inch PVA film; (c) a photograph of the Al/c-Al₂O₃ pattern transferred onto a 4-inch silicon wafer; and (d) a magnified optical image of the Al/c-Al₂O₃ pattern from the red box in figure (c).

FIG. 3 is a schematic diagram (a side view) of the manufacture of a van der Waals integrated top-gate two-dimensional field effect transistor based on c-Al₂O₃ dielectric.

FIG. 4 is a schematic diagram (a top view) of the manufacture of a van der Waals integrated top-gate two-dimensional field effect transistor based on c-Al₂O₃ dielectric.

FIG. 5 is an optical microscope image of a van der Waals integrated top-gate two-dimensional field effect transistor, wherein: (a) an optical microscope image of a complete structure of a top-gate transistor based on mechanically exfoliated MoS₂; (b) a magnified optical microscope image of a red box area in the figure (a); (c) an optical microscope image of a CVD MoS₂ top-gate transistor array; and (d) a magnified optical microscope image from the red box area in figure (c).

FIG. 6 shows batch manufacture of a c-Al₂O₃/MoS₂ field effect transistor on a four-inch CVD-MoS₂/sapphire substrate, wherein: (a) top-gate field effect transistor arrays on a 4-inch CVD-MoS₂/sapphire wafer; (b) a magnified optical microscope image from the red box in figure (a); (c) a magnified optical microscope image from the red box in figure (b); (d) a typical output curve of the c-Al₂O₃/MoS₂ field effect transistor; (e) transfer curves of 100 MoS₂ field effect transistors; and (f) the statistic distributions of on-off current ratio (Iₒₙ/I_{off}) and subthreshold swing (SS) from 100 devices.

### DESCRIPTION OF THE EMBODIMENTS

The present invention will be further illustrated with reference to specific examples. It should be understood that these examples are only for illustrating the present invention and are not intended to limit the scope of the present invention. Furthermore, it should be understood that after reading the teachings of the present invention, those skilled in the art can make various changes or modifications to the present invention, and these equivalents also fall within the scope defined by the appended claims.

### Example 1

Technical Route for the Preparation of Single-Crystalline c-Al₂O₃:

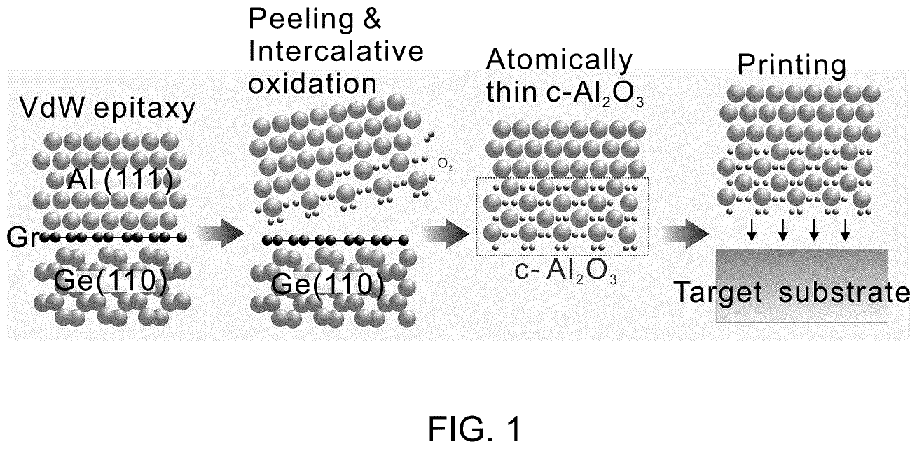

As shown in FIG. 1, this example proposes an epitaxial lift off and intercalative oxidation technique of a single-crystalline Al (111) thin film for the preparation of high-quality atomically thin single-crystalline Al₂O₃ (c-Al₂O₃) without requiring complex chemical processes or advanced equipment. Van der Waals epitaxy of the single-crystalline Al (111) thin film was performed on the Graphene/Ge (110) substrate by electron beam evaporation by using a single-crystalline graphene/germanium (Graphene/Ge) (110) substrate as a template. The single-crystalline Al thin film can be easily peeled off from the Graphene/Ge substrate due to the weak van der Waals force between single-crystalline Al and graphene. The single-crystalline Al thin film was peeled off from the Graphene/Ge substrate in a glovebox, at this time, the lower surface of the single-crystalline Al film will replicate the surface roughness of the atomically flat Graphene/Ge substrate, and the lower surface of atomically flat Al (111) was subjected to mild intercalative oxidation in an oxygen-deficient environment (0.2 ppm O₂) of a glovebox, eventually producing atomically thin single-crystalline c-Al₂O₃ on the lower surface of the single-crystalline Al (111) thin film. The Al/c-Al₂O₃ thin film can be transferred to any target substrate.

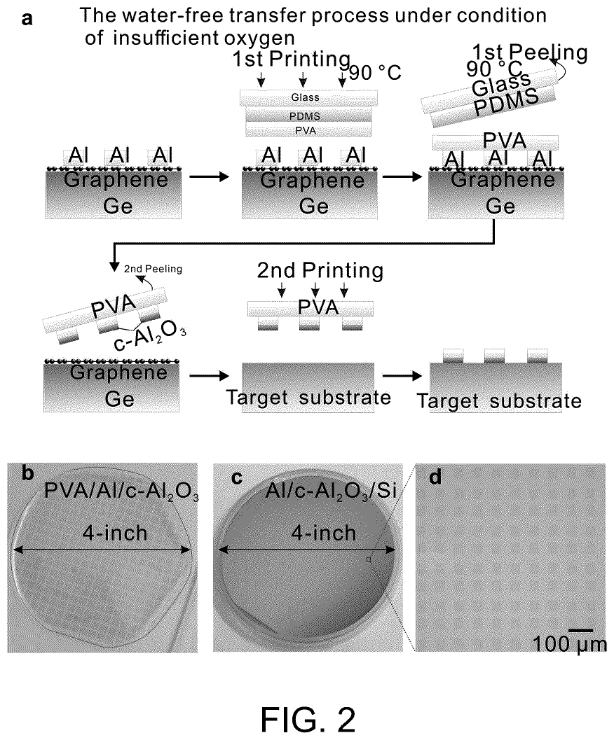

A process flow for the preparation and transfer of Al/c-Al₂O₃ patterns in an oxygen-deficient environment (0.2 ppm O₂) of a glovebox is shown in (a) of FIG. 2, and a detailed process flow was as follows:
(1) Al metal patterns were defined on a Graphene/Ge substrate by electron beam lithography/ultraviolet photolithography, and then the single-crystalline Al (111) metal thin film was epitaxially grown on the Graphene/Ge substrate by electron beam evaporation. After a lift-off process, a patterned single-crystalline Al (111) metal thin film was left on the Graphene/Ge substrate.
(2) Preparation of polyvinyl alcohol (PVA) film: an 8% PVA aqueous solution dropwise coated a SiO₂/Si substrate, waiting for the PVA aqueous solution to dry naturally at room temperature. After two days, the PVA film on the SiO₂/Si substrate was directly peeled off with tweezers, and the dried PVA film was subsequently attached to an elastic PDMS stamp by using the adhesive properties of PDMS (polydimethylsiloxane) itself, ensuring that the PVA film and PDMS were attached tightly without bubbles.
(3) The PVA film attached on the elastic PDMS stamp was physically laminated onto the Al metal pattern on the Graphene/Ge substrate by using a transfer platform in a glovebox, and heating was performed at 90° C. for 3 min. The PVA film will be vitrified at 90° C., and the vitrified PVA was released from PDMS onto the Graphene/Ge substrate, and then the substrate was cooled to room temperature.
(4) The PVA film was peeled off from the Graphene/Ge substrate in an oxygen-deficient environment of a glovebox (0.2 ppm O₂). During this process, the Al metal pattern was peeled off from the Graphene/Ge substrate onto the PVA film due to the weak van der Waals force between Al and graphene. The lower surface of the Al metal pattern replicated the surface roughness of the atomically flat Graphene/Ge substrate, and the atomically flat lower surface of the Al metal pattern underwent mild intercalative oxidation in the oxygen-deficient environment of the glovebox to form atomically thin single-crystalline c-Al₂O₃ on the lower surface of the single-crystalline Al metal pattern.
(5) The PVA film with the Al/c-Al₂O₃ pattern was attached to PDMS, and then the PVA film with the Al/c-Al₂O₃ pattern attached was physically laminated onto target substrates such as SiO₂/Si, sapphire, MoS₂, graphene and metal bottom electrodes by using a transfer platform, and heating was performed at 90° C. for 3 min, and finally the PVA film with the Al/c-Al₂O₃ pattern attached was released from PDMS onto the target substrate.
(6) The PVA film was dissolved using an anhydrous solvent dimethyl sulfoxide (DMSO) by heating at 70° C., and at this time, the Al/c-Al₂O₃ pattern was completely left on the target substrate, thus achieving van der Waals heterogeneous integration of Al/c-Al₂O₃ with any target substrate.
(b) to (d) of FIG. 2 are photographs and a magnified optical microscope image of peeling and transfer of a four-inch Al/c-Al₂O₃ pattern from a four-inch Graphene/Ge substrate onto a silicon wafer. The yield of peeling and transfer is close to 100%, and the transferred Al/c-Al₂O₃ pattern has no obvious damage or wrinkles.

### Example 2

Manufacture of Van Der Waals Integrated Top-Gate Two-Dimensional Field Effect Transistors Based on c-Al₂O₃ Dielectric:

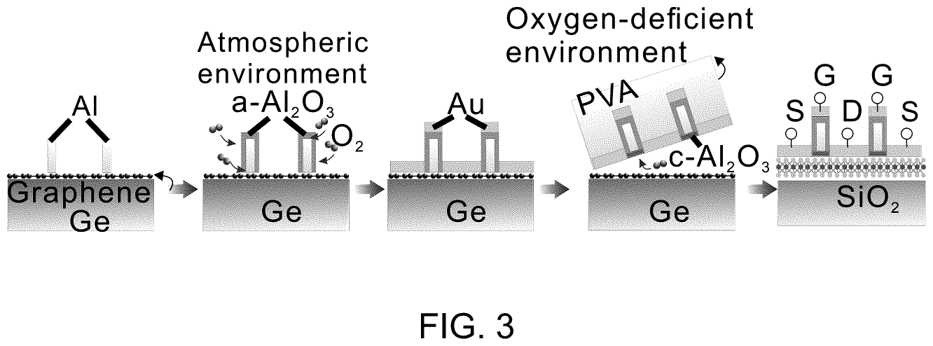

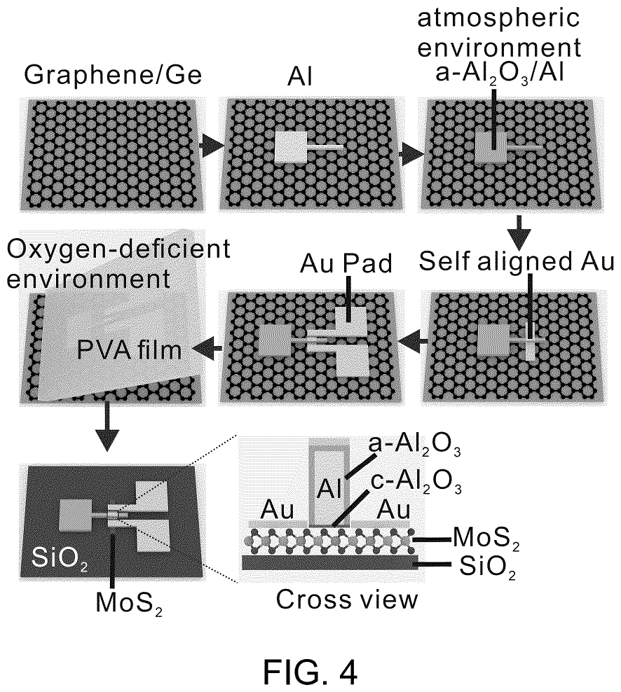

In order to utilize the c-Al₂O₃ dielectric produced by intercalative oxidation on the surface of the single-crystalline Al (111) for the preparation of two-dimensional field effect transistors, a one-step transfer process for metal contacts and Al/c-Al₂O₃ gate stacks was developed to prepare the van der Waals integrated top-gate two-dimensional field effect transistor. Process flow diagrams are shown in FIGS. 3 and 4.

A manufacture process for the van der Waals integrated two-dimensional top-gate field effect transistor was described in detail below:
(1) Gate electrode patterns were defined by electron beam lithography/ultraviolet photolithography, and single-crystalline Al (111) metal gate electrodes were allowed to epitaxially grow on a graphene/germanium substrate by electron beam evaporation. The upper surface and side wall of the Al gate electrode were allowed to be naturally oxidized in air to form amorphous aluminum oxide (a-Al₂O₃).
(2) Source-drain contact patterns were defined on both sides of the Al gate electrode by electron beam lithography/ultraviolet photolithography, and Au was allowed to deposit on both sides of the gate electrode by electron beam evaporation as source-drain contact electrodes.
(3) The Al gate electrode and the source-drain Au contact electrodes were peeled off from the graphene/germanium substrate using a PVA film in an oxygen-deficient environment of a glovebox (0.2 ppm O₂). At this time, the lower surface of the Al gate electrode was subjected to an intercalative oxidation process to produce c-Al₂O₃ dielectric.
(4) The PVA film, which carries the Au contact electrodes and Al/c-Al₂O₃ gate stacks, was attached to PDMS. A transistor structure attached to a PDMS/PVA stamp was then aligned and physically laminated onto mechanically exfoliated or CVD-grown two-dimensional materials, such as Graphene and MoS₂, using a transfer platform.
(5) Finally, PVA was dissolved using an anhydrous solvent dimethyl sulfoxide (DMSO).

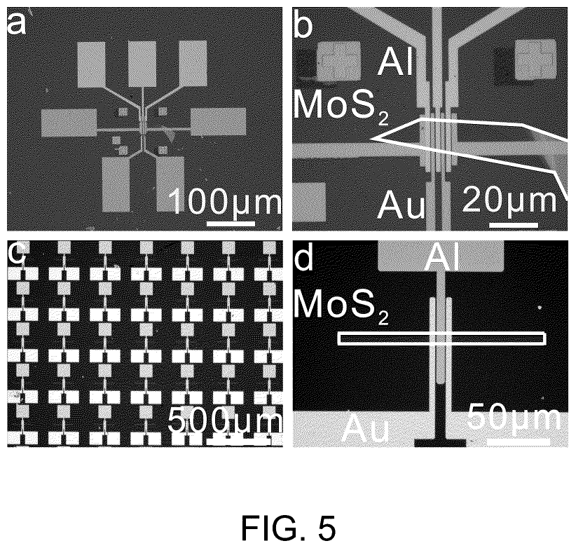

This method can be used to prepare either a single transistor or transistor arrays. (a) and (b) of FIG. 5 are optical microscope images of a typical van der Waals integrated top-gate MoS₂ transistor manufactured by mechanically exfoliated MoS₂ on a SiO₂/Si substrate, and (c) and (d) of FIG. 5 are optical microscope images of transistor arrays manufactured by CVD MoS₂ on the sapphire substrate. The transferred transistor structure was complete with no wrinkles and cracks.

### All Van Der Waals Integrated Top-Gate MoS₂ Transistor Arrays:

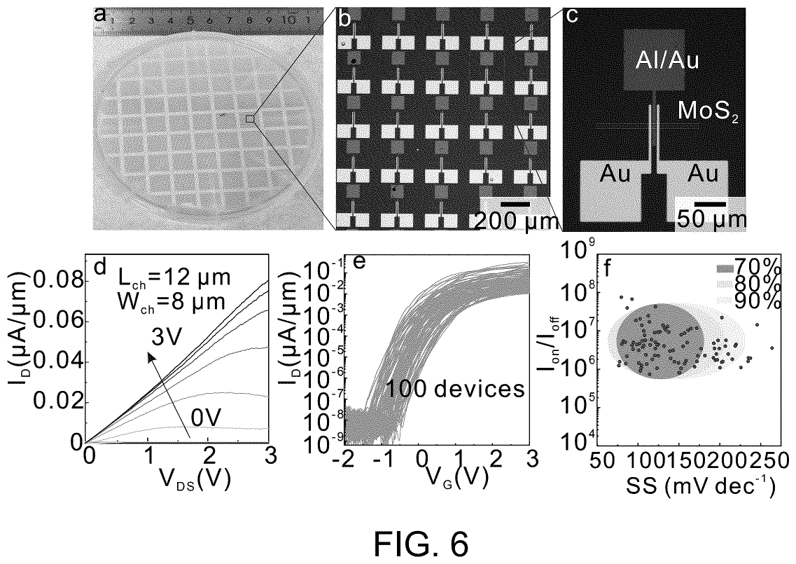

A photograph of transistor arrays manufactured on a four-inch CVD-MoS₂ wafer is shown in (a) of FIG. 6, the Au source-drain electrodes and the Al/c-Al₂O₃ gate stacks which were pre-manufactured on the graphene/Ge substrate were completely transferred onto MoS₂, and magnified optical microscope images in (b) and (c) of FIG. 6 show no significant electrode wrinkles and cracks. The MoS₂ transistor features a channel length (L_{ch}) of 12 μm, a channel width (W_{ch}) of 8 μm, and a gate length (L_{g}) of 6 m, with a 3 m spacing between the gate and source-drain electrodes. As shown in (d) of FIG. 6, a typical output curve of the transistor shows excellent electrostatic control of the MoS₂ channel by the Al/c-Al₂O₃ gate stack. Transfer curves from 100 MoS₂ field effect transistors are shown in (e) of FIG. 6, and these devices exhibit the typical n-type characteristics with excellent uniformity. The statistical distributions of the on/off current ratio (Iₒₙ/I_{off}) and the subthreshold swing (SS) extracted from 100 devices are shown in (f) of FIG. 6. Seventy percent of the devices show SS values in the range of 75-175 mV/dec and Iₒₙ/I_{off} higher than 10⁶, which are among the best for CVD-MoS₂ transistors.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A single-crystalline Al₂O₃ dielectric compatible with two-dimensional materials, wherein van der Waals epitaxy of a single-crystalline Al thin film is performed on a single-crystalline graphene/germanium (110) substrate, the single-crystalline Al thin film is peeled off from the graphene/germanium substrate, and intercalative oxidation is performed to produce the single-crystalline Al₂O₃ dielectric compatible with two-dimensional materials on the lower surface of the single-crystalline Al thin film.

2. A preparation method for a single-crystalline Al₂O₃ dielectric compatible with two-dimensional materials, comprising the steps of:
(1) defining Al metal patterns on a single-crystalline graphene/germanium substrate by electron beam lithography/ultraviolet photolithography, and then allowing a single-crystalline Al thin film to epitaxially grow on the graphene/germanium substrate by electron beam evaporation; and after a lift-off process, allowing a patterned single-crystalline Al thin film to be left on the graphene/germanium substrate;
(2) physically laminating a PVA film attached on an elastic polydimethylsiloxane (PDMS) stamp onto the patterned single-crystalline Al thin film in the step (1) with a transfer platform in a glovebox, and performing heating, releasing a vitrified PVA film from PDMS onto the graphene/germanium substrate, then cooling the substrate to room temperature;
(3) peeling off the PVA film from the graphene/germanium substrate, and peeling off the patterned single-crystalline Al thin film in the step (1) from the graphene/germanium substrate onto the PVA film in an oxygen-deficient environment of a glovebox, and forming atomically thin single-crystalline c-Al₂O₃, i.e., the single-crystalline Al₂O₃ dielectric compatible with two-dimensional materials, on the lower surface of the patterned single-crystalline Al thin film.

3. The preparation method according to claim 2, wherein the heating in the step (2) is performed at a temperature of 80-100° C. for 1-5 min.

4. The preparation method according to claim 2, wherein the oxygen-deficient environment of the glovebox in the step (3) refers to an oxygen concentration of 0.2 ppm or less.

5. Use of the single-crystalline Al₂O₃ dielectric compatible with two-dimensional materials according to claim 1 in the manufacture of an integrated device.

6. The use according to claim 5, wherein the integrated device is a two-dimensional field effect transistor or a two-dimensional transistor array thereof.

7. The use according to claim 6, wherein a method for manufacturing the two-dimensional field effect transistor comprises the steps of:
(1) defining a gate electrode pattern by electron beam lithography/ultraviolet photolithography, allowing a single-crystalline Al metal gate electrode to epitaxially grow on a graphene/germanium substrate by electron beam evaporation, and allowing the upper surface and side wall of the Al gate electrode to be naturally oxidized in air to form amorphous aluminum oxide;
(2) defining source-drain contact patterns on both sides of the Al gate electrode by electron beam lithography/ultraviolet photolithography, and allowing Au to deposit on both sides of the gate electrode by electron beam evaporation as source-drain contact electrodes;
(3) peeling off the Al gate electrode and the source-drain Au contact electrodes from the graphene/germanium substrate with a PVA film in an oxygen-deficient environment of a glovebox, and subjecting the lower surface of the Al gate electrode to an intercalative oxidation process to produce c-Al₂O₃ dielectric;
(4) attaching the PVA film, which carries the Au contact electrodes and Al/c-Al₂O₃ gate stacks, to PDMS, and then aligning and physically laminating a transistor structure attached to a PDMS/PVA stamp onto mechanically exfoliated or CVD-grown two-dimensional materials using a transfer platform;
(5) dissolving the PVA film with an organic solvent to obtain the two-dimensional field effect transistor.

8. The use according to claim 6, wherein the two-dimensional transistor array is obtained by mass production of the manufactured two-dimensional field effect transistors.
